(19) United States
(12) Patent Application Publication
(10) Pub. No.: US 2007/0102714 A1
(43) Pub. Date: May 10, 2007

(54) DISPLAY DEVICE AND MANUFACTURING METHOD THEREOF

(75) Inventors: Sung-Soo LEE, Suwon-si (KR); Un-Cheol SUNG, Anyang-si (KR); Sang-Pil LEE, Seoul (KR)

Correspondence Address: H.C. PARK & ASSOCIATES, PLC, 8500 LEESBURG PIKE, SUITE 7500, VIENNA, VA, 22182, US

(73) Assignee: SAMSUNG ELECTRONICS CO., LTD., Suwon-si (KR)

(21) Appl. No.: 11/558,113

(22) Filed: Nov. 9, 2006

(30) Foreign Application Priority Data
Nov. 10, 2005 (KR) 10-2005-0107536

(51) Int. Cl. H01L 33/00

(52) U.S. Cl. 257/88; 257/E33.005

(57) ABSTRACT

The present invention discloses a display device having a substrate; a light emitting layer arranged on the substrate; a first electrode arranged on the light emitting layer; and a second electrode facing the first electrode, where the light emitting layer is arranged between the second electrode and the first electrode. A thickness of the first electrode varies depending on the wavelength of a light emitted from the light emitting layer.

### CROSS-REFERENCE TO RELATED APPLICATIONS

This application claims priority from and the benefit of Korean Patent Application No. 10-2005-0107536, filed on Nov. 10, 2005, which is hereby incorporated by reference for all purposes as if fully set forth herein.

### BACKGROUND OF THE INVENTION

1. Field of the Invention

The present invention relates to a display device and a manufacturing method thereof, and more particularly, to a display device having a electrode layer with different thicknesses depending on a wavelength of emitted light, and a manufacturing method thereof.

2. Description of the Background

Recently, an organic light emitting diode (OLED) has become more popular. The OLED may be a passive matrix OLED or an active matrix OLED according to its driving method. The passive matrix OLED has a simple production process, but requires an increase in power consumption because of an increase in its size and resolution. Thus, the passive matrix OLED is preferred in small display devices. On the other hand, the active matrix OLED has a wide screen and high resolution requiring a complex production process.

In the active matrix OLED, a thin film transistor is provided in every pixel region to control the emission of light from an organic light emitting layer in each pixel region. A pixel electrode is provided in each of the pixel regions, and each pixel electrode is insulated electrically from an adjacent pixel electrode so that each pixel electrode is independently driven. A wall, which is higher than the pixel electrode, is formed on every pixel region to prevent a short-circuit between adjacent pixel electrodes and to partition adjacent pixel regions. A hole injecting layer and the organic light emitting layer are sequentially formed on each pixel electrode that is formed between the walls. A common electrode is formed on the organic light emitting layer.

The OLED may be a bottom emission OLED or a top emission OLED according to an emission direction of light generated by the organic light emitting layer.

In the bottom emission OLED, light generated by the organic light emitting layer is emitted toward the thin film transistor. The bottom emission OLED has a stable process, but experiences a decrease in an aperture ratio due to the thin film transistor and wires.

In the top emission OLED, light generated by the organic light emitting layer is emitted to the outside through the common electrode. Thus, the top emission OLED may have a higher aperture ratio without a decrease in the aperture ratio due to the thin film transistor; however, a transparent common electrode is not easily formed.

The transparent electrode layer may be an anode or cathode in both the bottom emission and top emission OLEDs. According to its thickness, the transparent electrode layer may have a varying transmittance corresponding to a wavelength of the emitted light. Generally, the thickness of the transparent electrode layer is uniform regardless of the wavelength of light.

### SUMMARY OF THE INVENTION

This invention provides a display device which includes a electrode layer having different thicknesses to improve light transmittance.

This invention also provides a manufacturing method for a display device which includes a electrode layer having different thickness to improve light transmittance.

Additional aspects and/or advantages of the present invention will be set forth in part in the description which follows and, in part, will be obvious from the description, or may be learned by practice of the present invention.

The foregoing and/or other aspects of the present invention can be achieved by providing a display device including a substrate, a light emitting layer arranged on a substrate, a first electrode arranged on the light emitting layer, and a second electrode facing the first electrode, where the light emitting layer is arranged between the second electrode and the first electrode. A thickness of the first electrode varies depending on the wavelength of a light emitted from the light emitting layer.

The foregoing and/or other aspects of the present invention can also be achieved by providing a method of manufacturing a display device including the steps of forming a light emitting layer on a substrate, where the light emitting layer comprises a red light emitting layer, a blue light emitting layer, and a green light emitting layer; forming a first electrode layer on the light emitting layer; forming a second electrode layer on the first electrode layer at a position corresponding to the red light emitting layer and the green light emitting layer, where the second electrode layer is thicker than the first electrode layer; and forming a third electrode layer on the second electrode layer at a position corresponding to the red light emitting layer, where the third electrode layer is thicker than the second electrode layer.

The foregoing and/or other aspects of the present invention can also be achieved by providing a method of manufacturing a display device including the steps of forming a light emitting layer on a substrate, where the light emitting layer comprises a red light emitting layer, a blue light emitting layer, and a green light emitting layer; forming a first electrode layer on the light emitting layer; forming a second electrode layer on the first electrode layer at a position corresponding to the green light emitting layer and the blue light emitting layer, where the second electrode layer is thinner than the first electrode layer; and forming a third electrode layer on the second electrode layer at a position corresponding to the blue light emitting layer, where the third electrode layer is thinner than the second electrode layer.

The foregoing and/or other aspects of the present invention can also be achieved by providing a method of manufacturing a display device including the steps of forming a light emitting layer on a substrate; applying a transparent electrode material on the light emitting layer; applying a photosensitive material on the transparent electrode material; and forming a transparent electrode layer having different thicknesses by patterning the photosensitive material using a mask, the mask comprising non-uniform light transmittance regions.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 illustrates a sectional view of a display device according to a first exemplary embodiment of the present invention.

FIG. 2 illustrates a graph of light transmittance according to the thickness of a transparent electrode layer according to the first exemplary embodiment of the present invention.

FIG. 3A, FIG. 3B, FIG. 3C, FIG. 3D, FIG. 3E, FIG. 3F, FIG. 3G, and FIG. 3H illustrate a manufacturing method of the display device according to the first exemplary embodiment of the present invention.

FIG. 4A, FIG. 4B, FIG. 4C, FIG. 4D, and FIG. 4E illustrate a manufacturing method of a display device according to a second exemplary embodiment of the present invention.

FIG. 5A, FIG. 5B, and FIG. 5C illustrate a manufacturing method of a display device according to a third exemplary embodiment of the present invention.

FIG. 6A, FIG. 6B, and FIG. 6C illustrate a manufacturing method of a display device according to a fourth exemplary embodiment of the present invention.

### DETAILED DESCRIPTION OF EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative size of layers and regions may be exaggerated for clarity. Like reference numerals in the drawings denote like elements.

It will be understood that when an element such as a layer, film, region or substrate is referred to as being “on” or “connected to” another element or layer, it can be directly on or directly connected to the other element or layer, or intervening elements or layers may also be present. In contrast, when an element is referred to as being “directly on” or “directly connected to” another element or layer, there are no intervening elements or layers present.

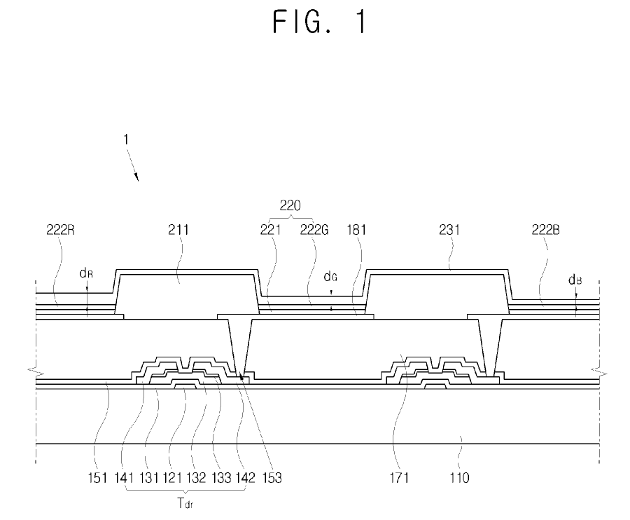

FIG. 1 illustrates a sectional view of a display device according to a first exemplary embodiment of the present invention, which illustrates a driving transistor Tdr connected to a second electrode 181.

As shown in FIG. 1, a gate electrode 121 is arranged on a substrate 110 which may include an insulating material such as glass, quartz, ceramic or plastic. A gate insulating film 131 which may be formed from silicon nitride (SiNx) is arranged on the substrate 110 and the gate electrode 121.

A semiconductor layer 132 made of amorphous silicon and an ohmic contact layer 133 comprising a n+ hydrogenated amorphous silicon highly doped with an n-type dopant are sequentially arranged on the gate insulating film 131 corresponding to the gate electrode 121. The ohmic contact layer 133 is separated into two parts, each part of the ohmic contact layer 133 being arranged on either side of the gate electrode 121 with the gate electrode 121 being the center.

A source electrode 141 and a drain electrode 142 are arranged on the ohmic contact layer 133 and the gate insulating film 131. The source electrode 141 and the drain electrode 142 are arranged on either side of the gate electrode 121 with the gate electrode 121 being the center.

A passivation layer 151 is arranged on the source electrode 141, the drain electrode 142, and a portion of the semiconductor layer 132 exposed between the source electrode 141 and the drain electrode 142. The passivation layer 151 may be formed from silicon nitride (SiNx). A portion of the passivation layer 151 corresponding to the drain electrode 142 is removed.

An organic layer 171 is arranged on the passivation layer 151 which covers the thin film transistor Tdr. An upper portion of the organic layer 171 is generally flat, and a portion of the organic layer 171 corresponding to the location of the drain electrode 142 may be partially removed. The organic layer 171 may be formed from any one of benzocyclobutene (BCB), olefin, acrylic resin, polyimide, Teflon, cytop and perflourocyclobutane (FCB).

A second electrode 181 is arranged on the organic layer 171. The second electrode 181 may be an anode for supplying holes an organic layer 220 and refer to a pixel electrode. Generally, the second electrode 181 may be formed from an opaque material such as aluminum, silver, nickel or chrome. The second electrode 181 is connected to the drain electrode 142 through a contact hole 153. The second electrode 181 includes a metal, which has a high work function for efficiently supplying holes to the organic layer 220. Alternatively, the second electrode 181 may be formed from a transparent conductive material similar to a first electrode 231. In this case, light may be emitted to opposite sides of the substrate 110 instead of being solely emitted toward the first electrode 231.

A wall 211 surrounding the second electrode 181 is arranged on a portion of the second electrode 181 and the organic layer 171. The wall 211 partitions the second electrode 181 to define a pixel region. The wall 211 prevents the source electrode 141 and the drain electrode 142 of the thin film transistor Tdr from short-circuiting with the first electrode 231. The wall 211 may be made from a photosensitive material, which has heat-resistant and solvent-resistant properties, such as acrylic resin and polyimide resin, or an inorganic material such as silicon oxide (SiO₂) and titanium oxide (TiO₂). The wall 211 may be formed with a dual-layered structure having organic and inorganic layers.

The organic layer 220 is arranged on a portion of the second electrode 181 which is not covered by the wall 211. The organic layer 220 includes a hole injecting layer 221 and a light emitting layer 222 (222R, 222G and 222B).

The hole injecting layer 221 may be formed from a hole injecting material, such as poly 3,4-ethylenedioxythiophene (PEDOT) and polystyrene sulfonic acid (PSS). The hole injecting layer 221 is formed by mixing the hole injecting material with water and then processing the mixture by an inkjet method in an aquatic suspension state.

The light emitting layer 222 includes a red light emitting layer 222R, a green light emitting layer 222G, and a blue light emitting layer 222B. The light emitting layers 222R, 222G and 222B emit light in different colors onto the neighboring second electrode 181. The emitted light have different wavelength bands according to the respective colors. The light emitting layer 222 may also be formed by an inkjet method.

The first electrode 231 is arranged on the wall 211 and the light emitting layer 222. The first electrode 231 may be a cathode or a common electrode for supplying electrons to the light emitting layer 222. A hole supplied by the second electrode 181 and an electron transmitted from the first electrode 231 are combined in the light emitting layer 222 to become an exciton, thereby generating light during a non-activation process of the exciton. The first electrode 231 may be formed from a transparent conductive material, such as indium tin oxide (ITO) or indium zinc oxide (IZO). Light emitted from the light emitting layer 222 is transmitted to the outside of the display device 1 through the first electrode 231.

The first electrode 231 varies in thickness depending on the colors of the emitted light, i.e., dependent on the light emitted from the light emitting layers 222R, 222G and 222B. The thickness d_{R} of the first electrode 231 arranged on the red light emitting layer 222R is greater than the thickness d_{G} of the first electrode 231 arranged on the green light emitting layer 222G. The thickness d_{B} of the first electrode 231 arranged on the blue light emitting layer 222B is less than the thickness d_{G} of the first electrode 231 arranged on the green light emitting layer 222G. As described above, every material has a different wavelength band having its highest light transmittance according to the thickness of the first electrode 231 formed from that material. The highest transmittance of red light is available when the first electrode 231, formed of ITO or IZO, has a thickness of about 1000 Å to about 2000 Å. The highest transmittance of green light is available when the first electrode 231, formed of ITO or IZO, has a thickness of about 1300 Å to about 1500 Å. The highest transmittance of blue light is available when the first electrode 231, formed of ITO or IZO, has a thickness of about 900 Å to about 1200 Å. Preferably, the thickness d_{R} of the first electrode 231 arranged on the red light emitting layer 222R is about 1700 Å to about 2000 Å. Also, the thickness d_{G} of the first electrode 231 arranged on the green light emitting layer 222G is about 1300 Å to about 1500 Å, and the thickness d_{B} of the first electrode 231 arranged on the blue light emitting layer 222B is about 900 Å to about 1200 Å. Light transmittance characteristics may be improved by providing the first electrode 231 with the thickness having the highest transmittance depending on the wavelength of light.

The display device 1 according to the first exemplary embodiment of the present invention is a top emission OLED, which emits light toward the first electrode 231. However, in a bottom emission OLED, which emits light toward the substrate 110, an anode may vary in thickness depending on the wavelength of light.

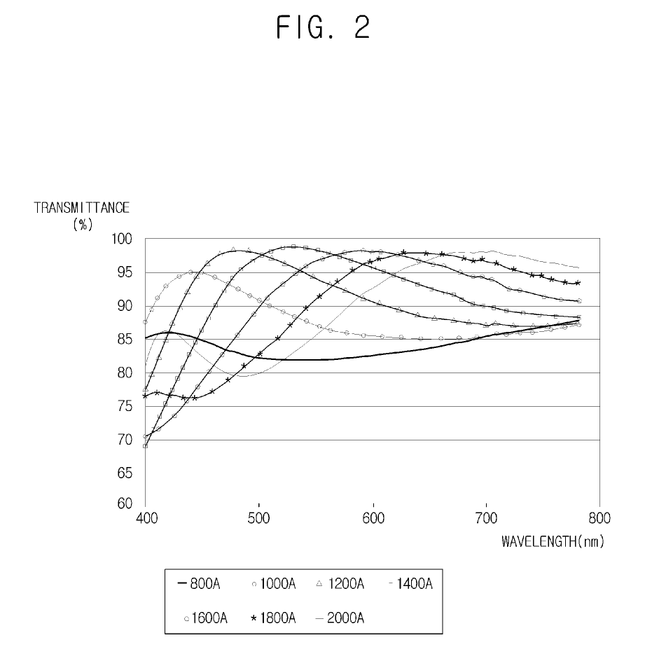

FIG. 2 illustrates a graph of light transmittance with respect to the thickness of the first electrode 231. Referring to FIG. 2, the thickness of the first electrode 231 according to the first exemplary embodiment of the present invention will be described.

FIG. 2 illustrates a plurality of curves representing light transmittance versus a wavelength corresponding to the first electrode 231 with a predetermined thickness.

At the highest light transmittance (app 98%) for a red-colored light, the first electrode 231 has a thickness of about 1700 Å to about 2000 Å, more particularly about 1800 Å, and the red-colored light has a wavelength band of about 650 to about 700 nm. At the highest light transmittance (app 98%) for a green-colored light, the first electrode 231 has a thickness of about 1300 Å to about 1500 Å, more particularly about 1400 Å, and the green-colored light has a wavelength band of about 530 to about 500 nm. At the highest light transmittance (app 95%) for a blue-colored light, the first electrode 231 has a thickness of about 900 Å to about 1200 Å, more particularly about 1000 Å, and the blue-colored light having a wavelength band of about 530 to about 550 nm.

The first electrode 231 in FIG. 1 includes at least a single layer of ITO. Alternatively, the first electrode 231 may further include other alloy layers. In this case, a single light transmittance corresponding to a single thickness may be calculated by multiplying the light transmittance of the respective first electrodes. Then, a thickness of the first electrode 231 corresponding to the highest light transmittance per wavelength band may be calculated from the transmittance curves with respect to the thicknesses for the respective first electrodes using FIG. 2.

For example, when the first electrode 231 includes a double layer having an alloy metal layer formed of magnesium and silver, and a layer formed of ITO, the transmittance of the metal layer with a thickness of about 2000 Å is about 60% and the transmittance of the metal layer with a thickness of 1000 Å is 70% in the red wavelength band, while the transmittance of the ITO layer with a thickness of 1000 Å is 85% in the red wavelength band. Thus, the thickness of the metal layer having the highest transmittance can be determined per wavelength using FIG. 2.

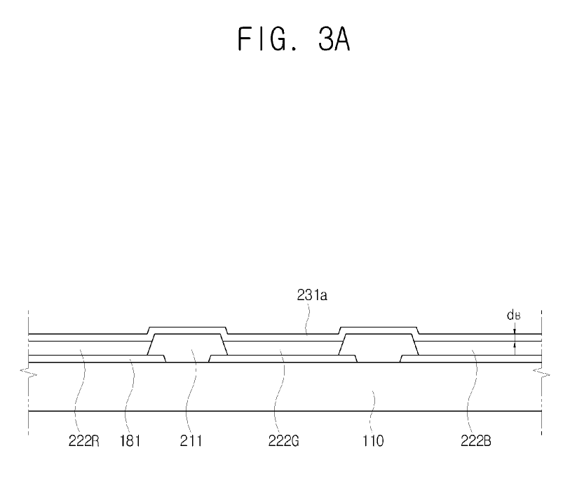

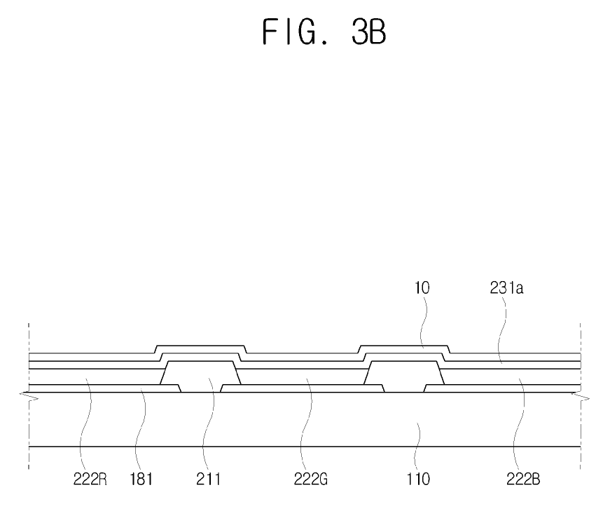

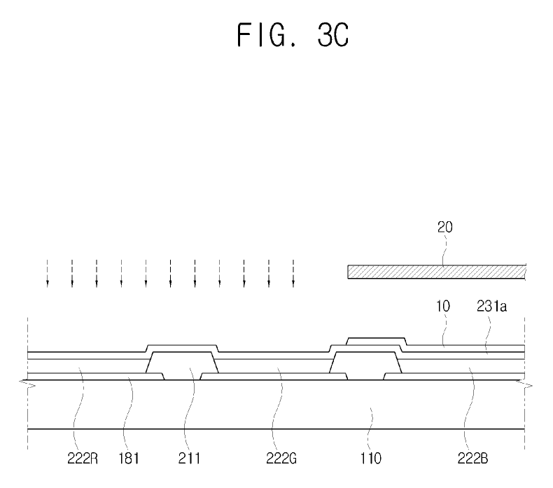

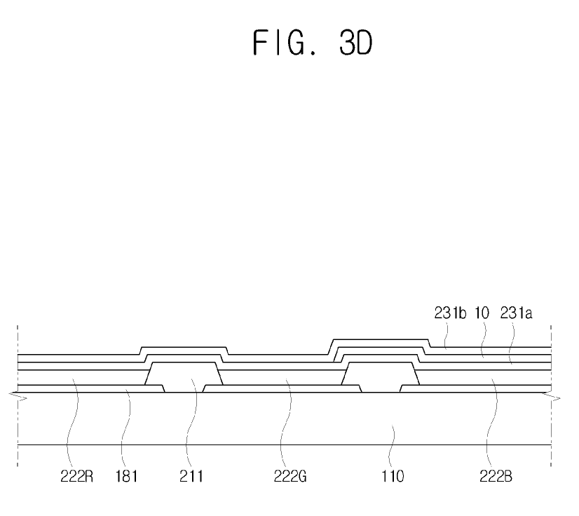

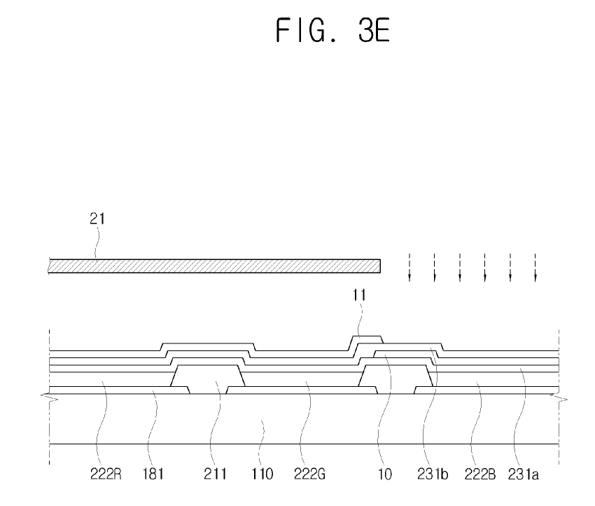

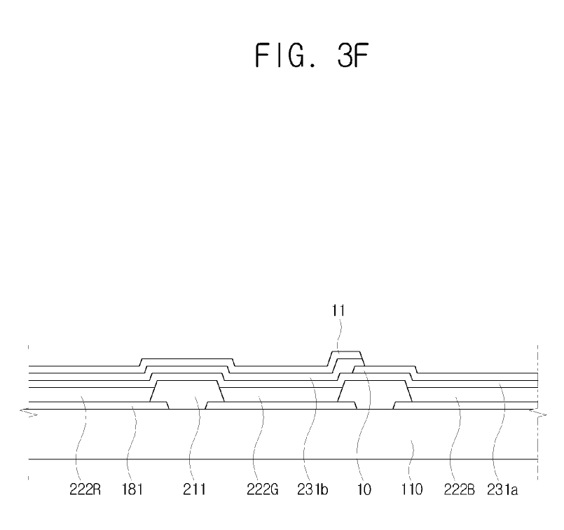

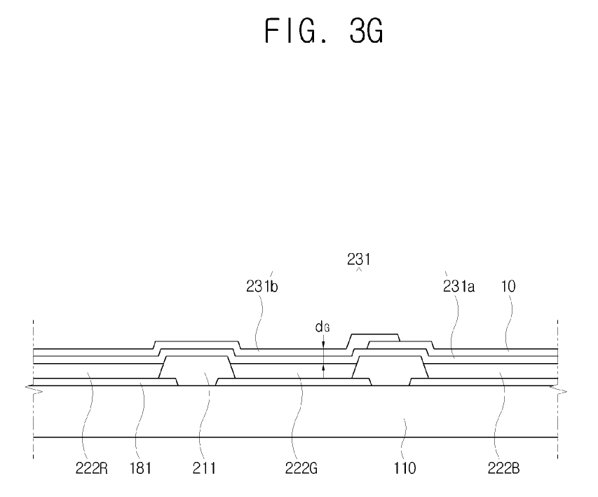

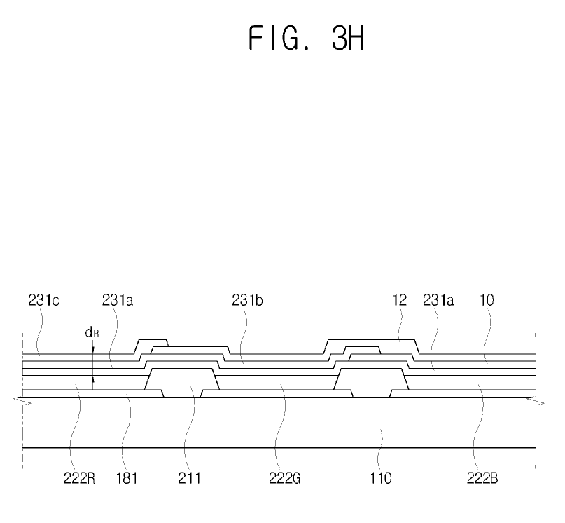

FIG. 3A, FIG. 3B, FIG. 3C, FIG. 3D, FIG. 3E, FIG. 3F, FIG. 3G, and FIG. 3H illustrate a method of manufacturing the display device 1 according to the first exemplary embodiment of the present invention. For convenience of description, a transistor is not shown Additionally, a first electrode material and a first electrode having the transparent electrode material are given an identical reference number 231, where the reference numbers 231a, 231b, and 231c designate a first electrode layer, a second electrode layer and a third electrode layer of the first electrode according to the forming sequence.

As shown in FIG. 3A, the second electrode 181 is arranged on the substrate 110. The second electrode 181 is electrically connected to a driving transistor (not shown) through the contact hole. The second electrode 181 may be formed by depositing a material through sputtering and then patterning.

The wall 211 is arranged on the substrate 110 to partition the second electrode 181 from an adjacent second electrode 181. The red light emitting layer 222R, the green light emitting layer 222G, and the blue light emitting layer 222B are sequentially arranged on a respective second electrode 181.

A first electrode layer 231a is arranged over the light emitting layers 222R, 222G, 222B and the wall 211. The thickness d_{B} of the first electrode layer 231a corresponds to the first electrode 231 which is arranged on the blue light emitting layer 222B.

As shown in FIG. 3B, a first photosensitive material 10 is arranged on the first electrode layer 231a. The foregoing process includes a pre-baking process for removing moisture from the first electrode layer 231a on which the first photosensitive material 10 is to be applied to improve adhesion between the first photosensitive material 10 and the first electrode layer 231a; a spin coating process for uniformly coating the first photosensitive material 10 onto the first electrode layer 231a by using centrifugal force; and a soft-baking process for vaporizing a solvent remaining on the first photosensitive material 10 to cure the first photosensitive material 10.

As shown in FIG. 3C, the first photosensitive material 10 on the red light emitting layer 222R and the green light emitting layer 222G is removed using a first mask 20, thereby exposing the first electrode layer 231a. The first photosensitive material 10 is removed through well-known exposure, etching, and development processes.

As shown in FIG. 3D, a second transparent layer 231b is deposited on the exposed first electrode layer 231a, and the first photosensitive material 10.

As shown in FIG. 3E, a second photosensitive material 11 is deposited on the second electrode layer 231b, and then the second photosensitive material 11 remaining on the blue light emitting layer 222B is removed by a second mask 21. The second electrode layer 231b is exposed above the blue light emitting layer 222B where the second photosensitive material 11 has been removed.

As shown in FIG. 3F, the second electrode layer 231b on the blue light emitting layer 222B is removed by an etching liquid.

After removing the second photosensitive material 11 remaining on the red light emitting layer 222R and the green light emitting layer 222G, the first electrode 231, which includes the first electrode layer 231a and the second electrode layer 231b, is formed on the red light emitting layer 222R and the green light emitting layer 222G, as shown in FIG. 3g. The thickness d_{G} of the first electrode 231 on the green light emitting layer 222G corresponds to the sum of the thicknesses of the first electrode layer 231a and the second electrode layer 231b. Thus, the thickness d_{G} of the first electrode 231 on the green light emitting layer 222G is greater than the thickness d_{B} of the first electrode layer 231a on the blue light emitting layer 222B.

By repeating the process illustrated in FIGS. 3B to 3G, a third electrode layer 231c is formed, where the first electrode 231, which includes the first electrode layer 231a, the second electrode layer 231b, and the third electrode layer 231c is arranged on the red light emitting layer 222R, as shown in FIG. 3H. A third photosensitive material 12 is arranged on the first electrode 231 of the green light emitting layer 222G and the blue light emitting layer 222B, and the first photosensitive material 10.

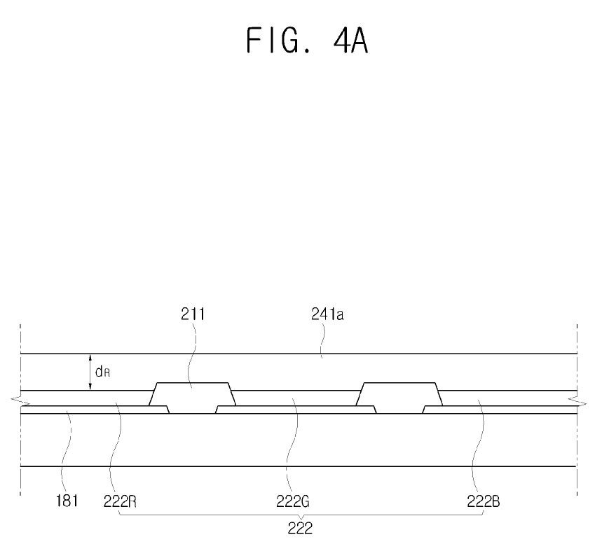

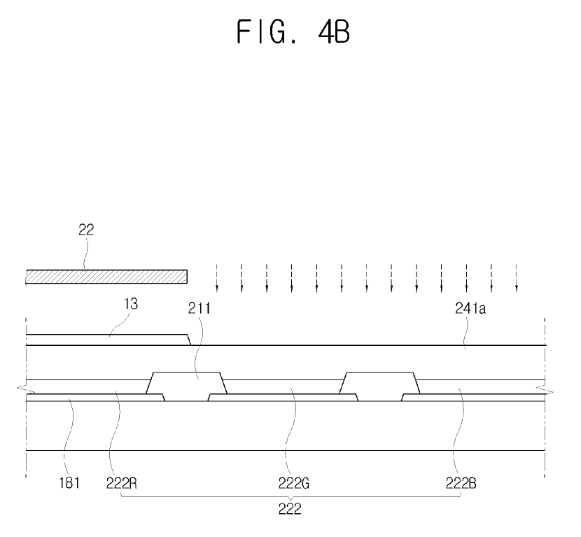

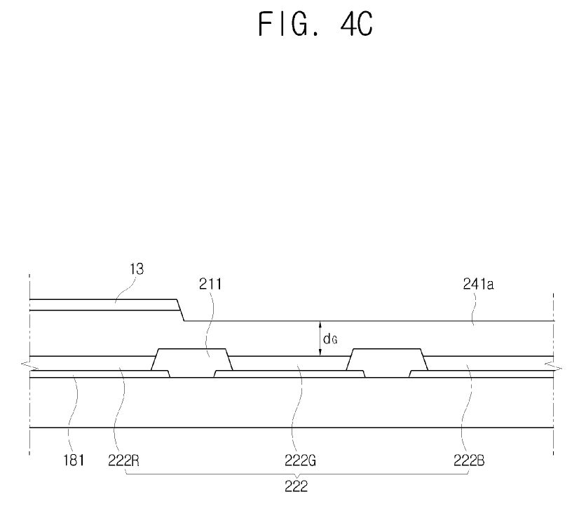

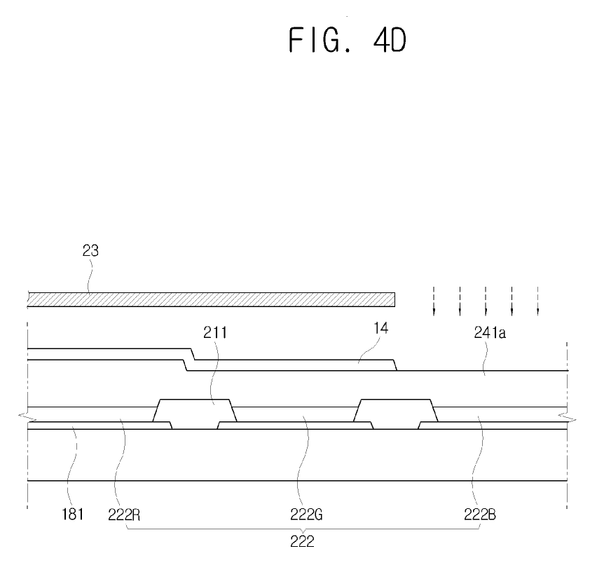

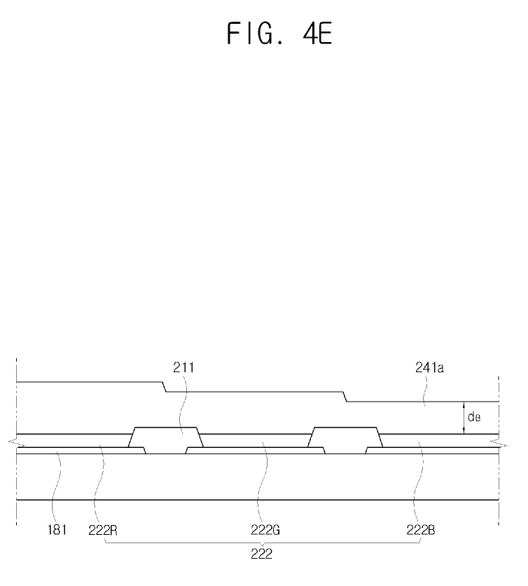

FIG. 4A, FIG. 4B, FIG. 4C, FIG. 4D, and FIG. 4E illustrate a method of manufacturing a display device according to a second exemplary embodiment of the present invention. In the display device 1 according to the first exemplary embodiment, the thinnest electrode layer 231a and the thicker electrode layers 231b and 231c are formed through photolithography by using the masks 20 and 21, and the photosensitive materials 10 and 11. In the display device according to the second exemplary embodiment of the present invention, the thickest electrode layer 241a may be formed first, followed by formation of the thinner electrode layers.

As shown in FIG. 4A, the first electrode 241a is arranged on a light emitting layer 222, a wall 211, and a second electrode 181.

As shown in FIG. 4B, a first photosensitive material 13 is arranged on the transparent electrode layer 241a. The first photosensitive material 13 remaining on a green light emitting layer 222G and a blue light emitting layer 222B is removed using a third mask 22, which covers the first photosensitive material 13 at a position corresponding the red light emitting layer 222R.

As shown in FIG. 4C, the first electrode 241a on the green light emitting layer 222G and the blue light emitting layer 222B is etched so that a thickness d_{G} of the first electrode remains on the green light emitting layer 222G using an etching liquid. The etching time is determined by the degree of reaction of the first electrode 241a with the etching liquid.

As shown in FIG. 4D, a second photosensitive material 14 is arranged on the first electrode 241a. The second photosensitive material 14 arranged on the blue light emitting layer 222B is removed using a fourth mask 23, which covers the second photosensitive material 14 at a position corresponding to the blue light emitting layer 222B.

As shown in FIG. 4E, the first electrode 241a on the blue light emitting layer 222B is etched so that a thickness d_{B} of the first electrode remains on the blue light emitting layer 222B using the etching liquid.

With the foregoing process, the first electrodes are formed with various thicknesses by using the photolithography described in the first exemplary embodiment of the present invention.

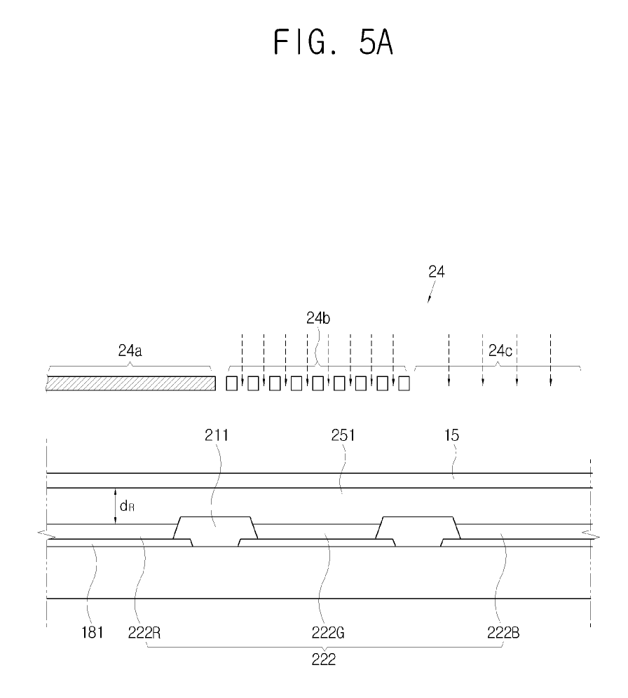

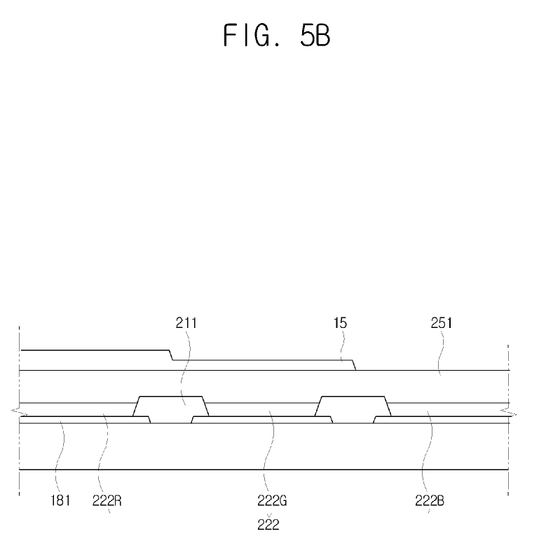

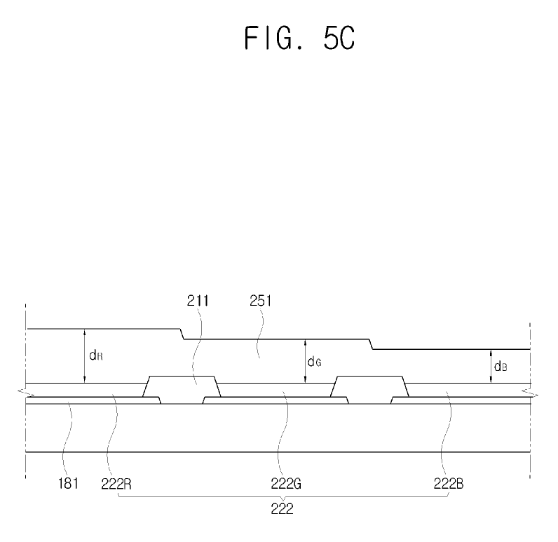

Hereinafter, a method of manufacturing a display device according to a third exemplary embodiment of the present invention will be described with reference to FIG. 5A, FIG. 5B, and FIG. 5C.

The display device according to the present invention is manufactured through photolithography by using a mask. Using a single mask having different light transmittance, a first electrode with different thicknesses may be formed through etching, exposure, and development.

As shown in FIG. 5A, a fifth mask 24 includes a transmission region 24b and a transmission region 24c, which are not uniform. More specifically, the fifth mask 24 includes a block region 24a, which completely blocks light; a transmission region 24c, which allows light to be completely transmitted; and a semi-transmission region 24b, which allows light to be partially transmitted. A plurality of slit patterns is arranged in the semi-transmission region 24b, thereby controlling the amount of transmitted light.

A photosensitive material 15 is deposited on a light emitting layer 222, a wall 211, and a second electrode 181, and then the photosensitive material 15 is exposed with light through the fifth mask 24.

Next, the photosensitive material 15 is formed through etching and development, as shown in FIG. 5B. The photosensitive material 15 deposited on a red light emitting layer 222R maintains its initial thickness, while the photosensitive material 15 deposited on a blue light emitting layer 222B is completely removed. The photosensitive material 15 deposited on a green light emitting layer 222G is developed at an intermediate level to form a different thickness.

Next, a first electrode 251 is etched according to the thickness of the photosensitive material 15 using an etching liquid, thereby forming the first electrode 251 as shown in FIG. 5c.

The different thicknesses of the first electrode 251 may be formed using the single mask 24, allowing the first electrode 251 to be partially exposed through the slit patterns of the semi-transmission region 24b.

A mask 24 according to another exemplary embodiment of the present invention may include a semi-transparent layer instead of physical patterns, such as the slit patterns of the semi-transmission region 24b. Light transmittance may be adjusted through the adjustment of the semi-transparent degree of the semi-transparent layer, thereby offering a similar effect as with the slit patterns.

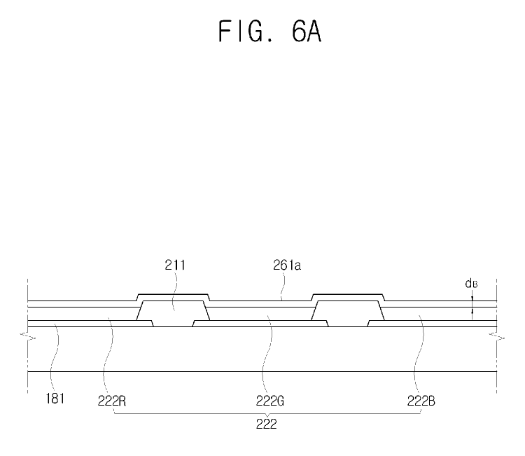

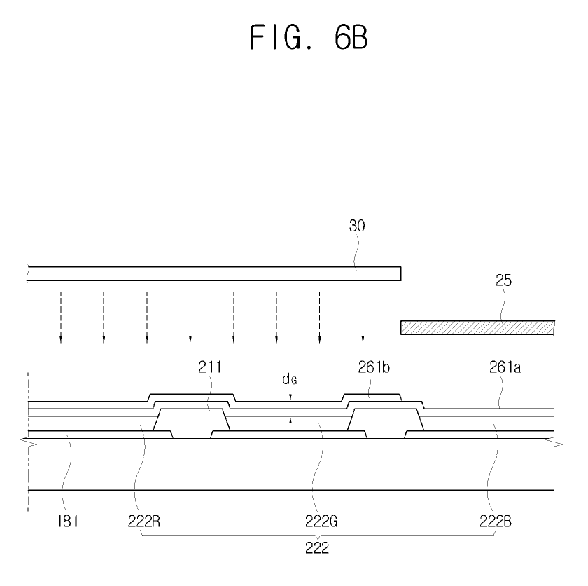

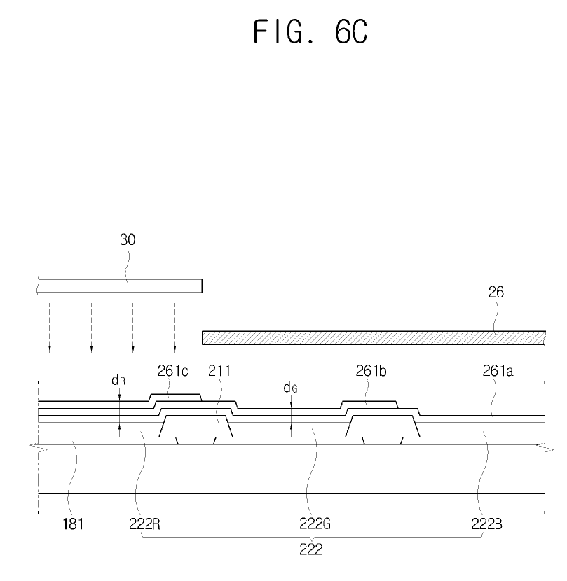

A method of manufacturing a display device according to a fourth exemplary embodiment of the present invention will be described with reference to FIG. 6A, FIG. 6B, and FIG. 6C.

First, as shown in FIG. 6A, a first electrode layer 261a, which has a thickness d_{B} of the first electrode arranged on a blue light emitting layer 222B is formed.

Then, as shown in FIG. 6B, a second electrode layer 261b is arranged using a first shadow mask 25, which exposes the first electrode layer 261 a at a position corresponding to a red light emitting layer 222R and a green light emitting layer 222G. The second electrode layer 261b is formed by a sputtering method, which uses plasma discharge and includes use of indium tin oxide (ITO) or indium zinc oxide (IZO) 30. Then, the first electrode, including the first electrode layer 261a and the second electrode layer 261b, with the desired thickness d_{G} is formed on the green light emitting layer 222G.

As shown in FIG. 6c, a third electrode layer 261c is formed through the sputtering method by using a second shadow mask 26, which exposes the first electrode layer 261a and the second electrode layer 261b at a position corresponding to the red light emitting layer 222R alone.

The display device can be manufactured without difficulty by sputtering ITO or IZO 30 through the shadow masks 25 and 26.

According to another exemplary embodiment, electrode layers may be independently formed using a shadow mask which is open at locations corresponding to the respective light emitting layers, instead of being formed with the gradually-enlarged thickness.

The present invention provides a display device which has a electrode layer with different thicknesses to improve light transmittance, and various manufacturing methods thereof.

It will be apparent to those skill in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A display device, comprising:
a substrate;
a light emitting layer arranged on the substrate;
a first electrode arranged on the light emitting layer; and
a second electrode facing the first electrode, the light emitting layer arranged between the second electrode and the first electrode,
wherein a thickness of the first electrode varies depending on the wavelength of a light emitted from the light emitting layer.

2. The display device of claim 1, wherein the light emitting layer comprises a red light emitting layer, a green light emitting layer, and a blue light emitting layer,
wherein the thickness of the first electrode on the red light emitting layer is greater than the thickness of the first electrode on the green light emitting layer, and
wherein the thickness of the first electrode on the blue light emitting layer is less than the thickness of the first electrode on the green light emitting layer.

3. The display device of claim 2, wherein the thickness of the first electrode on the red light emitting layer is about 1,700 Å to about 2,000 Å.

4. The display device of claim 2, wherein the thickness of the first electrode on the green light emitting layer is about 1,300 Å to about 1,500 Å.

5. The display device of claim 2, wherein the thickness of the first electrode on the blue light emitting layer is about 900 Å to about 1,200 Å.

6. The display device of claim 1, wherein the second electrode is arranged between the substrate and the light emitting layer, and
the emitted light is emitted toward the first electrode.

7. The display device of claims 1, wherein the first electrode comprises a transparent layer.

8. The display device of claim 7, wherein the transparent electrode layer comprises at least one of indium tin oxide (ITO) and indium zinc oxide (IZO).

9. The display device of claims 1, wherein the second electrode comprises a metal layer.

10. A method of manufacturing a display device, comprising:
forming a light emitting layer on a substrate, the light emitting layer comprising a red light emitting layer, a blue light emitting layer, and a green light emitting layer;
forming a first electrode layeron the light emitting layer;
forming a second electrode layer on the first electrode layer at a position corresponding to the red light emitting layer and the green light emitting layer, the second electrode layer being thicker than the first electrode layer; and
forming a third electrode layer on the second electrode layer at a position corresponding to the red light emitting layer, the third electrode layer being thicker than the second electrode layer.

11. The method of claim 10, wherein forming the second electrode layer comprises:
applying a first photosensitive material on the first electrode layer;
exposing the first electrode layer on the red light emitting layer and the green light emitting layer by patterning the first photosensitive material;
depositing a transparent electrode material on the first photosensitive material and the exposed first electrode layer;
applying a second photosensitive material on the transparent electrode material; and
removing the transparent electrode material on the blue light emitting layer.

12. The method of claim 10, wherein forming the second electrode layer comprises forming the second electrode layer using a shadow mask having an opening corresponding to the green light emitting layer, and
forming the third electrode layer comprises forming the third electrode layer using a shadow mask having an opening corresponding to the red light emitting layer.

13. The method of claim 12, wherein the thickness of the third electrode layer on the red light emitting layer is about 1,700 Å to about 2,000 Å.

14. The method of claim 12, wherein the thickness of the second electrode layer on the green light emitting layer is about 1,300 Å to about 1,500 Å.

15. The method of claim 12, wherein the thickness of the first electrode layer on the blue light emitting layer is about 900 Å to about 1,200 Å.

16. A method of manufacturing a display device, comprising:
forming a light emitting layer on a substrate, the light emitting layer comprising a red light emitting layer, a blue light emitting layer, and a green light emitting layer;
forming a first electrode layer on the light emitting layer;
forming a second electrode layer on the first electrode layer at a position corresponding to the green light emitting layer and the blue light emitting layer, the second electrode layer being thinner than the first electrode layer; and
forming a third electrode layer on the second electrode layer at a position corresponding to the blue light emitting layer, the third electrode layer being thinner than the first electrode layer.

17. The method of claim 16, wherein forming the second electrode layer comprises:
applying a photosensitive material on the first electrode layer;
removing the photosensitive material on the green light emitting layer and the blue light emitting layer; and
etching the first electrode layer.

18. A method of manufacturing a display device, comprising:
forming a light emitting layer on a substrate;
applying a transparent electrode material on the light emitting layer;
applying a photosensitive material on the transparent electrode material; and
forming a transparent electrode layer having different thicknesses by patterning the photosensitive material using a mask, the mask comprising non-uniform light transmittance regions.

19. The method of claim 18, wherein the mask comprises a plurality of slit patterns.

20. The method of claim 18, wherein the mask comprises a semi-transparent layer.
